(19) United States
(12) Patent Application Publication
(10) Pub. No.: US 2007/0103210 A1
(43) Pub. Date: May 10, 2007

(54) Power-on reset circuit for an integrated circuit

(75) Inventor: Kuo-Chun Hsu, Miaoli (TW)

Correspondence Address: FINNEGAN, HENDERSON, FARABOW, GARRETT & DUNNER;LLP, 901 NEW YORK AVENUE, NW, WASHINGTON, DC, 20001-4413, US

(73) Assignee: Taiwan Semiconductor Manufacturing Company, Ltd.

(21) Appl. No.: 11/267,142

(22) Filed: Nov. 7, 2005

(51) Int. Cl. H03L 7/00

(52) U.S. Cl. 327/143

(57) ABSTRACT

A power-on reset circuit for an integrated circuit has a trigger unit that includes (i) a first voltage drop element with a first terminal for coupling to a supply voltage, and a second terminal; (ii) a second voltage drop element with a first terminal, coupled to the second terminal of the first voltage drop element, and a second terminal; and (iii) an inverter with an input, coupled to the first terminal of the second voltage drop element, and an output. A discharge unit is provided to conduct a current from the trigger unit during a decrease of the supply voltage to decrease the voltage at the input of the first inverter, and substantially block current from the trigger unit during an increase of the supply voltage.

### TECHNICAL FIELD

This invention relates generally to providing a power-on reset signal for an integrated circuit.

### BACKGROUND

When a power condition of an integrated circuit (IC) changes from a low to a high voltage level, one or more semiconductor devices in the IC can enter undesirable logic states. For example, devices in the IC can be left in uncertain logic states after the power of the IC is switched on or after some disturbance is applied to the power of the IC.

A power-on reset circuit is implemented to reset the logic states of the IC to desired values by providing a reset signal. FIG. 1 is an illustration of an example of a conventional power-on reset circuit 100 comprising a resistor 110, a capacitor 120, a Schmitt trigger 130, and an inverter 140. The reset circuit 100 receives a supply voltage 150 at a node 160 and is connected to ground at a node 170. The power-on reset circuit 100 develops a trigger voltage at a node 180 (hereafter trigger voltage 180). The inverter 140 provides an outputted reset signal 190.

FIG. 2 shows the relationship among the supply voltage 150, trigger voltage 180, and reset signal 190 as a function of time for the conventional power-on reset circuit 100 of FIG. 1.

During a high-speed, short-duration glitch 200 of electrical power to the IC from an external impulse, such as a power failure or electromagnetic interference, the power-on reset circuit 100 cannot generate a desirable reset signal 190 fast enough to respond to the power glitch 200. For example, during the power glitch 200, along a negative slope 210 of the supply voltage 150 that is supplied to the IC, the trigger voltage 180 across the capacitor 120 lags behind the supply voltage 150, causing a missing reaction at the reset signal 190.

During a subsequent recovery of power, shown as a positive slope 220 of the supply voltage 150 in FIG. 2, the power-on reset circuit 100 will not deliver a full reset signal that is capable of effectively resetting the IC. Moreover, the reset signal may be delivered unreliably. The power-on reset circuit 100 triggers at a time that depends on the amplitude and slope of the supply voltage 150. However, a premature or late reset signal can cause functional failure of the IC.

Thus, it is desirable to provide a power-on reset circuit capable of effectively resetting an integrated circuit in response to a power condition. It is further desirable to provide a power-on reset circuit capable of reliably delivering the reset signal at a predetermined time.

### SUMMARY

Consistent with embodiments of the invention, there is provided a power-on reset circuit for an integrated circuit that comprises a trigger unit. A first voltage drop element of the trigger unit includes a first terminal and a second terminal, the first terminal for coupling to a supply voltage. A second voltage drop element of the trigger unit includes a first terminal and a second terminal, the first terminal of the second voltage drop element being coupled to the second terminal of the first voltage drop element. The trigger unit also includes a first inverter having an input terminal and an output terminal, the input terminal being coupled to the first terminal of the second voltage drop element. A second inverter of the trigger unit includes an input terminal and an output terminal, the input terminal of the second inverter being coupled to the output terminal of the first inverter. A switch of the trigger unit includes a first terminal, a second terminal, and a third terminal. The first terminal of the switch is coupled to the output terminal of the first inverter, the second terminal of the switch is coupled to the second terminal of the second voltage drop element, and the third terminal of the switch is for coupling to an electrical ground. The power-on reset circuit further comprises a discharge unit to conduct a current from the trigger unit during a decrease of the supply voltage to decrease a voltage at the input terminal of the first inverter, and substantially block current from the trigger unit during an increase of the supply voltage.

Also consistent with embodiments of the invention, there is provided a power-on reset circuit for an integrated circuit that comprises a trigger unit. A first voltage drop element of the trigger unit includes a first terminal and a second terminal, the first terminal for coupling to a supply voltage. A second voltage drop element of the trigger unit includes a first terminal and a second terminal, the first terminal of the second voltage drop element being coupled to the second terminal of the first voltage drop element. The trigger unit also includes an inverter including an input terminal and an output terminal, the input terminal of the inverter being coupled to the first terminal of the second voltage drop element. The power-on reset circuit further comprises a discharge unit. The discharge unit includes a voltage coupling element that includes a first terminal and a second terminal, the first terminal for coupling to the supply voltage. A third voltage drop element of the discharge unit includes a first terminal and a second terminal, the first terminal of the third voltage drop element being coupled to the second terminal of the voltage coupling element, and the second terminal of the third voltage drop element for coupling to the electrical ground. The discharge unit additionally includes a switch having a first terminal and a second terminal, the first terminal of the switch being coupled to the second terminal of the voltage coupling element, and the second terminal of the switch being coupled to the input terminal of the inverter.

### BRIEF DESCRIPTION OF THE DRAWINGS

The accompanying drawings, which are incorporated in and constitute a part of this specification, illustrate embodiments of the invention and, together with the description, serve to explain advantages and principles of the invention.

In the drawings,

FIG. 1 is a schematic diagram of a conventional power-on reset circuit for an integrated circuit;

FIG. 2 is a graph of two plots that show the relationship among supply voltage, input voltage, and outputted reset signal as a function of time for the conventional power-on reset circuit of FIG. 1;

FIG. 3 is a schematic block diagram of an exemplary embodiment of a power-on reset circuit for an integrated circuit;

FIG. 4 is a schematic diagram of an exemplary embodiment of the power-on reset circuit of FIG. 3;

FIG. 5 is a schematic diagram of an exemplary embodiment of the power-on reset circuit of FIG. 3;

FIG. 6 is a graph of two plots that show the relationship among the supply voltage, input voltage, and outputted reset signal as a function of time for the power-on reset circuit of FIG. 5;

FIG. 7 is a schematic diagram of an exemplary embodiment of the power-on reset circuit of FIG. 3;

FIG. 8 is a schematic diagram of an exemplary embodiment of the power-on reset circuit of FIG. 3;

FIG. 9 is a schematic diagram of an exemplary embodiment of the power-on reset circuit of FIG. 3; and

FIG. 10 is a schematic diagram of an exemplary embodiment of the power-on reset circuit of FIG. 3.

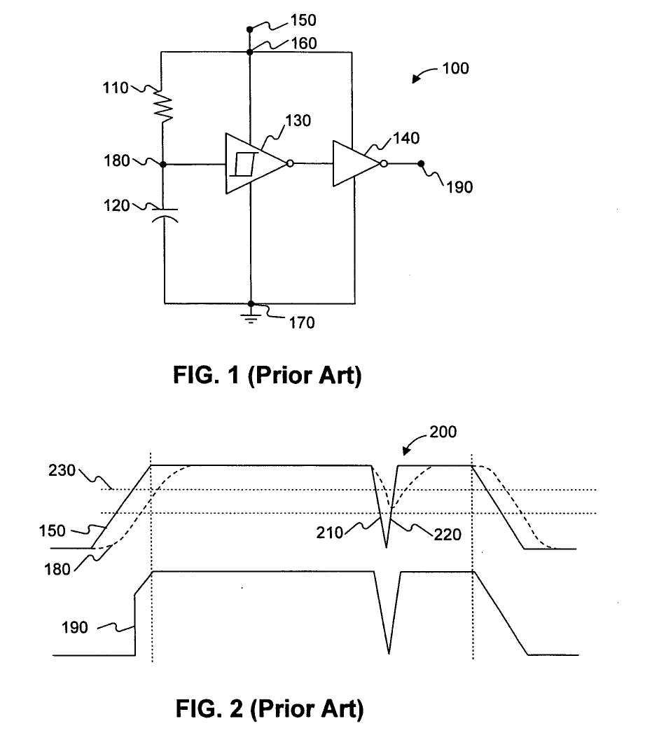

### DESCRIPTION OF THE EMBODIMENTS

Reference will now be made in detail to embodiments of the invention, examples of which are illustrated in the accompanying drawings. Wherever possible, the same reference numbers will be used throughout the drawings to refer to the same or like parts.

An integrated circuit (IC) comprises electrical circuitry, including a plurality of electronic components and electrical interconnections between the electronic components. The electronic components typically comprise active and passive electronic components, which include digital circuits. For example, the IC may comprise capacitors, resistors, field effect transistors (FETs), flip-flops, clock circuits, and/or memory devices. The IC may use “very large scale integration” (VLSI) or “ultra large scale integration” (ULSI), these terms designating degrees of spatial density of components in a single IC. Typically, the IC has the form of a monolithic semiconductor “chip.”

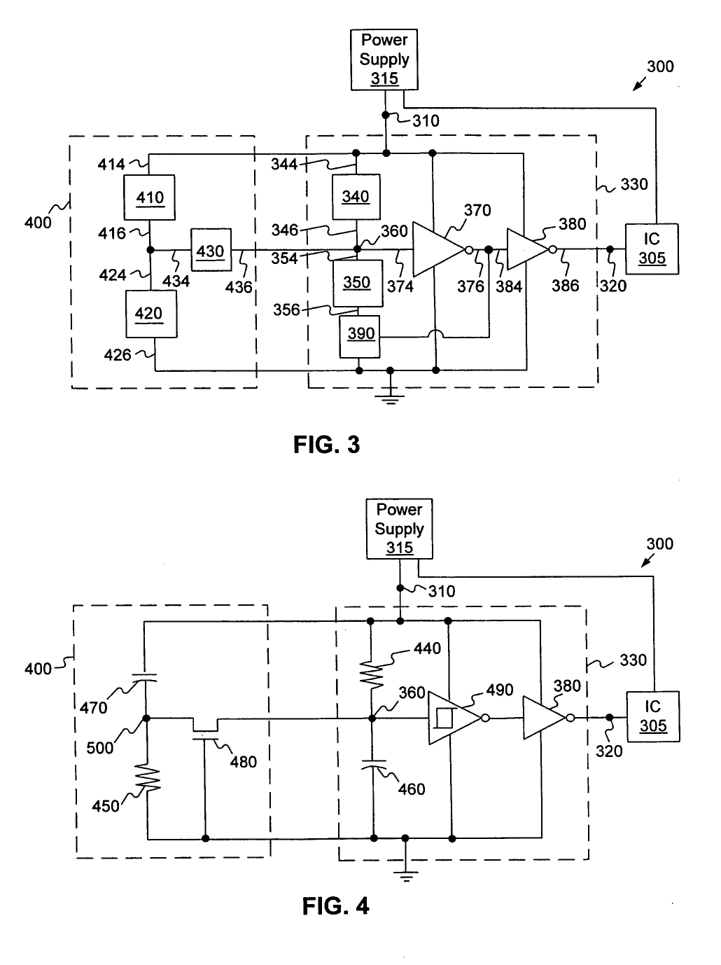

A power-on reset circuit 300 is provided to generate a reset signal at a node 320 for an IC 305, as illustrated in the schematic block diagram of an exemplary embodiment in FIG. 3. The power-on reset circuit 300 of FIG. 3 is provided only to illustrate the invention, and should not be used to limit the scope of the invention or its equivalents to the exemplary embodiments provided herein.

The power-on reset circuit 300 is adapted to receive a supply voltage V_{supply} at a node 310 from a power supply 315 coupled to the IC 305 and generate a reset signal at a node 320 in relation to a preselected power condition in the supply voltage V_{supply}. The power-on reset circuit 300 transmits the reset signal, carried as an output voltage Vₒᵤₜ at the node 320 of the power-on reset circuit 300, to control a supply of electrical power to the IC 305. For example, the reset signal may be received by the IC 305 at an enable terminal (not shown) that, based on the reset signal, regulates whether or not the IC 305 is coupled to the power supply 315.

Upon detection of the preselected power condition, the power-on reset circuit 300 outputs the reset signal, which goes from a “low” value to a “high” value, or alternatively from high to low, at node 320 to reset the digital circuits of the IC 305. This reset process sets the logical states of the IC 305 to known default values, when the power supply to the IC 305 is initially turned on or after a disruption in the power supply. The power supply disruption can include, for example, a black out, brown out, power spike, or other perturbance in the level of the supply voltage V_{supply} provided by the power supply.

The power-on reset circuit 300 comprises a trigger unit 330, which includes a first voltage drop element 340 and a second voltage drop element 350, to bias a trigger voltage Vₓ at a node 360. The first voltage drop element 340 includes a first terminal 344 and a second terminal 346, the first terminal 344 being adapted to be coupled to the power supply to receive the supply voltage V_{supply} at node 310. The second voltage drop element 350 includes a first terminal 354 and a second terminal 356. The first terminal 354 of the second voltage drop element 350 is coupled to the second terminal 346 of the first voltage drop element 340. Each of the first and second voltage drop elements 340, 350 is an electronic component adapted to produce a voltage drop between its first terminal 344, 354 and second terminal 346, 356. For example, the first or second voltage drop element 340, 350 may comprise a metal-oxide-semiconductor field effect transistor (MOSFET), capacitor, resistor, diode, junction field effect transistor (JFET), or bipolar junction transistor (BJT).

The trigger unit 330 further comprises a first inverter 370 having an input terminal 374 and an output terminal 376. The input terminal 374 of the first inverter 370 is coupled to the first terminal 354 of the second voltage drop element 350. The first inverter 370 may comprise, for example, a Schmitt trigger that outputs a voltage with a hysteresis relationship to its input voltage. The Schmitt trigger switches the output voltage from low to high when its input voltage reaches a first threshold value. However, the output voltage is switched back from high to low when the input voltage of the Schmitt trigger reaches a second threshold value that is lower than the first threshold value. Alternatively, the first inverter 370 may comprise a “standard inverter” that outputs a voltage without any substantial hysteresis relationship to its input voltage, such that the output voltage can be mapped one-to-one to the input voltage. The output voltage of the standard inverter is switched when the input voltage crosses substantially the same threshold voltage from either direction.

The trigger unit 330 also comprises a second inverter 380 including an input terminal 384 and an output terminal 386. The input terminal 384 of the second inverter 380 is coupled to the output terminal 376 of the first inverter 370. The second inverter 380 is adapted to receive the output voltage from the first inverter 370 and transmit the reset signal 320 as the output voltage Vₒᵤₜ at node 320. The second inverter 380 is an optional element, which may be included depending on a magnitude of the output voltage from the first inverter 370.

The trigger unit 330 may further comprise a first switch 390 to substantially prevent leakage current through the trigger unit 330 in a power-on quiescent stage. The first switch 390 is adapted to disconnect the second voltage drop element 350 from ground when the supply voltage V_{supply} at node 310 is greater than or equal to a high threshold voltage Vₜₕ. When the supply voltage V_{supply} at node 310 is less than or equal to a low threshold voltage Vₜₗ, the first switch 390 electrically grounds the second terminal 356 of the second voltage drop element 350. If there is substantially no current leakage through the first and second voltage drop elements 340, 350 due to electrical characteristics of other electronic components in the power-on reset circuit 300, such as if the second voltage drop element 350 does not permit any substantial leakage of direct current (DC) from node 360 to ground, then it may not be necessary to include the first switch 390 in the power-on reset circuit 300.

The power-on reset circuit 300 further comprises a rapid discharge unit 400 adapted to selectively conduct current from the trigger unit 330 in relation to a rate of change of the supply voltage V_{supply} at node 310. During a preselected condition of the supply voltage V_{supply}, the rapid discharge unit 400 selectively conducts current from the trigger unit 330 to decrease the trigger voltage Vₓ at node 360. For example, the rapid discharge unit 400 may be adapted to drain current from the trigger unit 330 during a decrease of the supply voltage V_{supply} to more rapidly decrease the trigger voltage Vₓ. During an increase of the supply voltage V_{supply}, the rapid discharge unit 400 may be adapted to substantially block current from the trigger unit 330 to prevent interference with the trigger voltage Vₓ.

In one version, the rapid discharge unit 400 comprises a voltage coupling element 410 and a third voltage drop element 420. The voltage coupling element 410 comprises a first terminal 414 and a second terminal 416. The first terminal 414 of the voltage coupling element 410 is adapted to be coupled to the supply voltage V_{supply} of the power supply 315. The third voltage drop element 420 comprises a first terminal 424 and a second terminal 426, the first terminal 424 being coupled to the second terminal 416 of the voltage coupling element 410.

The rapid discharge unit 400 further comprises a second switch 430 adapted to decrease the trigger voltage Vₓ at node 360 by conducting current from the input terminal 374 of the first inverter 370 when the second switch 430 is in a turned-on state. The second switch 430 comprises a first terminal 434 and a second terminal 436. The first terminal 434 of the second switch 430 is coupled to the second terminal 416 of the voltage coupling element 410, while the second terminal 436 of the second switch 430 is coupled to the input terminal 374 of the first inverter 370.

FIG. 4 is a schematic diagram of an exemplary embodiment of the power-on reset circuit 300 of FIG. 3. Here, the first and third voltage drop elements 340, 420 of FIG. 3 comprise first and second resistors 440, 450, respectively. The second voltage drop element 350 and the voltage coupling element 410 of FIG. 3 comprise first and second capacitors 460, 470, respectively. In this example, the first switch 390 is unnecessary and is not included in the power-on reset circuit shown in FIG. 4 because there is substantially no leakage of direct current (DC) through the capacitor 460. Further, in the exemplary power-on reset circuit 300 shown in FIG. 4, the second switch 430 of FIG. 3 comprises an n-channel metal-oxide-semiconductor (NMOS) field effect transistor (FET) 480 having a grounded gate and a grounded substrate. Finally, the first inverter 370 of FIG. 3 comprises a Schmitt trigger 490.

In operation, the rapid discharge unit 400 of FIG. 4 substantially blocks current from the trigger unit 330 during an increase in the supply voltage V_{supply} at node 310, and conducts current from the trigger unit 330 during a sufficiently fast decrease in the supply voltage V_{supply}. As the supply voltage V_{supply} increases from ground state, the second capacitor 470 couples a positive voltage from the power supply onto a source voltage V_{y} at a node 500 that is at the source of the NMOS FET 480. The NMOS FET 480 does not turn on because the gate-to-source voltage of the NMOS FET 480 has not exceeded the turn-on threshold voltage of the NMOS FET 480 at this point. Thus, the rapid discharge unit 400 substantially blocks current from the trigger unit 330. The first capacitor 460 charges to introduce a time delay until the trigger voltage Vₓ at node 360 reaches a turn-on threshold voltage of the Schmitt trigger 490. The time delay can be adjusted by selecting the capacitance value of the first capacitor 460. For example, a larger capacitance value results in a longer delay, whereas a smaller capacitance value results in a shorter delay.

If the supply voltage V_{supply} at node 310 decreases after the power-on quiescent stage, the second capacitor 470 couples a negative voltage from the power supply onto the source voltage V_{y} at node 500 that is at the source of the NMOS FET 480. The NMOS FET 480 is turned on because the gate-to-source voltage across the NMOS FET 480 exceeds the turn-on threshold voltage of the NMOS FET 480. Thus, the NMOS FET 480 discharges the first capacitor 460 through the second resistor 450 to ground to rapidly decrease the trigger voltage Vₓ at node 360. A faster decrease of the supply voltage V_{supply} at node 310 will couple a more negative voltage to the source voltage V_{y} at node 500 to result in a faster decrease of the trigger voltage Vₓ at node 360. When the trigger voltage Vₓ decreases sufficiently that the trigger voltage Vₓ is less than a threshold turn-off voltage of the Schmitt trigger 490, the output voltage Vₒᵤₜ is pulled down to electrical ground.

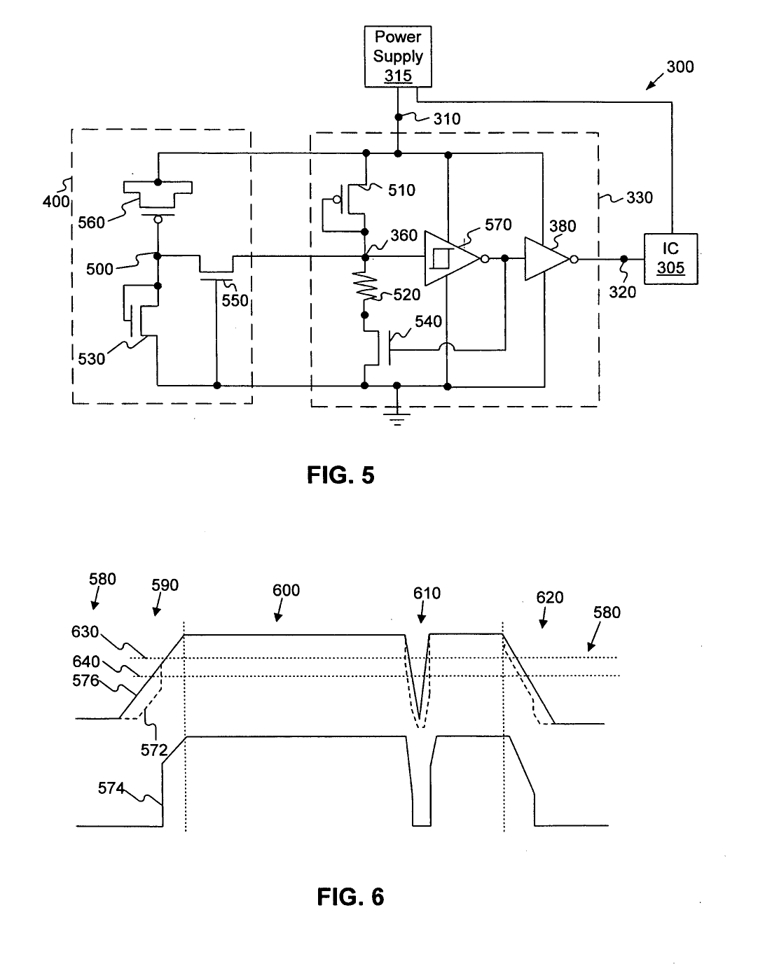

FIG. 5 is a schematic diagram of another exemplary embodiment of the power-on reset circuit 300. The first voltage drop element 340 of FIG. 3 comprises a “diode-connected” p-channel metal-oxide-semiconductor (PMOS) field effect transistor (FET) 510. PMOS FETs and NMOS FETs generally have a source, a drain, and a gate. With respect to either type of FET, when the drain and the gate of the FET are connected together to emulate a diode between the source and the drain of that FET, the FET is referred to as “diode-connected.” The second voltage drop element 350 of FIG. 3 comprises a resistor 520. The third voltage drop element 420 of FIG. 3 comprises a diode-connected NMOS FET 530. The first switch 390 and second switch 430 of FIG. 3 comprise first and second NMOS FETs 540, 550, respectively. The voltage coupling element 410 of FIG. 3 comprises a PMOS capacitor 560 having a drain, a source, and an n-well that are connected together to the supply voltage V_{supply}. Finally, the first inverter 370 of FIG. 3 comprises a Schmitt trigger 570.

The power-on reset circuit 300 of FIG. 5 is adapted to have a high threshold voltage Vₜₕ that is substantially independent of the rise time of the supply voltage V_{supply}. For example, the trigger unit 330 does not contain a capacitor that could otherwise cause a delayed response. The high threshold voltage Vₜₕ can be approximated by the following equation, in which V_{SGP} is the source-to-gate voltage of the diode-connected PMOS FET 560 and Vₜₙ is the turn-on threshold voltage of the Schmitt trigger 570:
Vₜₕ=2V_{SGP}+Vₜₙ (1)

FIG. 6 shows the relationship among the supply voltage V_{supply} 310, the trigger voltage Vₓ 360, and the outputted reset signal at node 320 as a function of time for the exemplary embodiment of the power-on reset circuit 300 in FIG. 5. The plots are exemplary embodiments of response curves of the trigger voltage Vₓ, shown as curve 572, and the outputted reset signal, shown as curve 574, as the supply voltage V_{supply}, shown as curve 576, passes through a power-off stage 580, a ramp-up stage 590, a power-on quiescent stage 600, a power disruption 610, a ramp-down stage 620, and back into the power-off stage 580.

In operation, the rapid discharge unit 400 substantially blocks current from the trigger unit 330 during the ramp-up stage 590. The second NMOS FET 550 of the rapid discharge unit 400 is turned off to substantially block the current from the input of the Schmitt trigger 570 in the trigger unit 330 through the rapid discharge unit 400 to ground, which allows the trigger voltage Vₓ 572 in the trigger unit 330 to ramp up quickly. While the supply voltage V_{supply} 576 is lower than a threshold voltage of the diode-connected PMOS FET 510, the trigger voltage Vₓ 572 remains at electrical ground while the output of the Schmitt trigger 570 is pulled up to a high voltage level. However, when the supply voltage V_{supply} 576 exceeds the threshold voltage of the diode-connected PMOS FET 510, the trigger voltage Vₓ 572 rises in proportion to the supply voltage V_{supply} 576. When the supply voltage V_{supply} 576 finally reaches a high threshold voltage Vₜₕ 630 of the power-on reset circuit 300, the output of the Schmitt trigger 570 changes from the high voltage level to a low voltage level. This turns off the first NMOS FET 540, causing the trigger voltage Vₓ 572 to jump to nearly the level of the supply voltage V_{supply} 576, as shown in FIG. 6. Current leakage through the trigger unit 330 is also substantially prevented while the first NMOS FET 540 is turned off, thereby conserving power through the power-on quiescent stage 600.

In the power-on quiescent stage 600, the power-on reset circuit 300 is adapted to tolerate fluctuations of the supply voltage V_{supply} 576 that are within a voltage window between a high threshold voltage Vₜₕ 630 and a low threshold voltage Vₜₗ 640. These fluctuations of the supply voltage V_{supply} 576 may be due, for example, to noise or electromagnetic interference. Typically, the voltage window is selected to fall within a known voltage tolerance of the electrical circuitry of the IC 305. For example, the specifications of the first PMOS FET 510, the resistor 520, and the Schmitt trigger 570, as shown in FIG. 5, may be selected to achieve a desired high threshold voltage Vₜₕ 630 or low threshold voltage Vₜₗ 640. Thus, the power-on reset circuit 300 is adapted to reliably generate an effective reset signal 574 when the supply voltage V_{supply} 576 falls outside of the preselected voltage window, but allow fluctuations of the supply voltage V_{supply} 576 within the voltage window.

During the power-on quiescent stage 600, the IC 305 may experience a power disruption 610 in which the supply voltage V_{supply} 576 momentarily drops from a higher level to a lower level. During the initial voltage decrease within the power disruption 610, the second NMOS FET 550 turns on to rapidly decrease the trigger voltage Vₓ 572. For example, the power-on reset circuit 300 may be adapted to decrease the trigger voltage Vₓ 572 faster than the rate of decrease of the supply voltage V_{supply} 576.

Returning to FIG. 5, the rapid discharge unit 400 is adapted to decrease the trigger voltage Vₓ at node 360 during a power disruption. As the supply voltage V_{supply} at node 310 decreases, the PMOS FET 560 of the rapid discharge unit 400, which serves as the voltage coupling element 410 of FIG. 3, couples a negative voltage to the source of the second NMOS FET 550. Since the gate of the second NMOS FET 550 is grounded, the second NMOS FET 550 will be turned on when the source voltage V_{y} at node 500 at the source of the second NMOS FET 550 is more negative than the turn-on threshold voltage of the second NMOS FET 550. When the supply voltage V_{supply} at node 310 swings down fast enough to cause the PMOS FET 560 to couple a sufficiently negative voltage to the source of the second NMOS FET 550, the second NMOS FET 550 turns on. Current then drains out of the trigger unit 330, through the second NMOS FET 550 and the diode-connected NMOS FET 530, to ground, to quickly decrease the trigger voltage Vₓ at node 360.

Furthermore, the power-on reset circuit 300 of FIG. 5 is adapted to have a low threshold voltage Vₜₗ that is dependent on the rate of decrease of the supply voltage V_{supply} at node 310. A more negative slope of the supply voltage V_{supply} will turn on the second NMOS FET 550 more strongly and therefore decrease the trigger voltage Vₓ at node 360 more rapidly. This may be advantageous because it allows the power-on reset circuit 300 to become more sensitive in response to a higher rate of decrease of the supply voltage V_{supply}.

As the supply voltage V_{supply} at node 310 begins to recover from the power disruption 610, the rapid discharge unit 400 substantially blocks current from the trigger unit 330. The trigger unit 330 can then increase the trigger voltage Vₓ at node 360 substantially absent interference from the rapid discharge unit 400 so that the recovery of the output voltage Vₒᵤₜ at node 320 is more reliable.

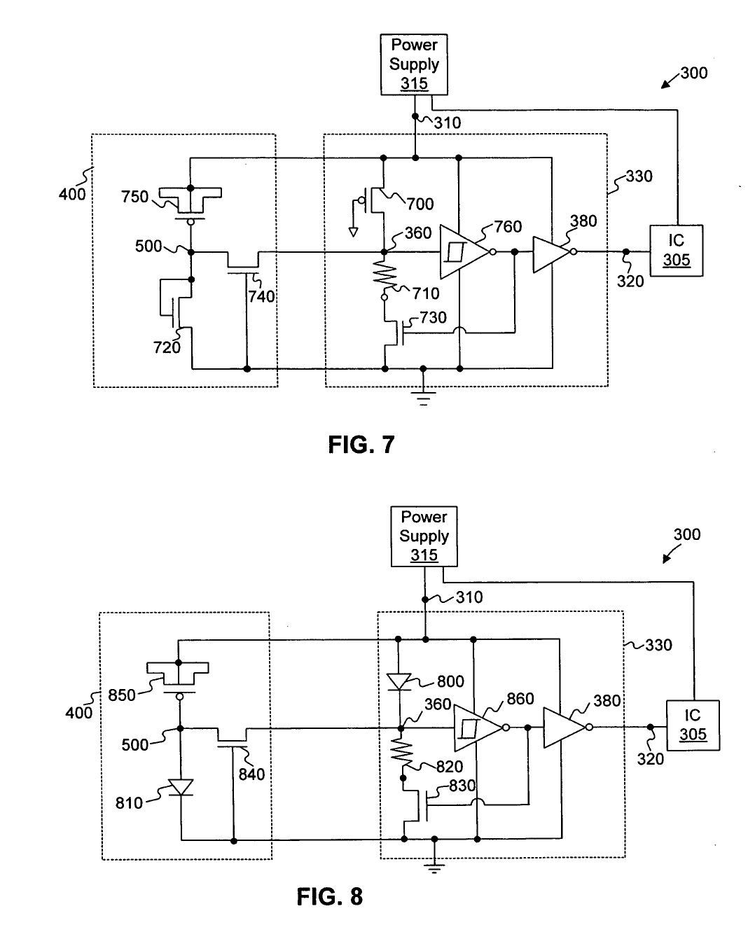

Another exemplary embodiment of the power-on reset circuit 300 is illustrated in the schematic diagram of FIG. 7. The first voltage drop element 340 of FIG. 3 comprises a gate-grounded PMOS FET 700 used as a resistor. The second voltage drop element 350 of FIG. 3 comprises a resistor 710. The third voltage drop element 420 of FIG. 3 comprises a diode-connected NMOS FET 720. The first and second switches 390, 430 of FIG. 3 comprise first and second NMOS FETs 730, 740, respectively. The voltage coupling element 410 of FIG. 3 comprises a PMOS capacitor 750 whose drain, source, and n-well are connected together and to the supply voltage V_{supply} at node 310. The first inverter 370 of FIG. 3 comprises a Schmitt trigger 760. When the supply voltage V_{supply} at node 310 exceeds a threshold voltage of the PMOS FET 700, the PMOS FET 700 turns on to increase the trigger voltage Vₓ at node 360. When the supply voltage V_{supply} 310 exceeds the high threshold voltage Vₜₕ of the power-on reset circuit 300, the Schmitt trigger 760 turns on, the NMOS FET 730, which serves as the first switch 390, turns off to substantially block current leakage through the resistor 710, and the output voltage Vₒᵤₜ at node 320 increases to supply power to the IC 305.

Yet another exemplary embodiment is illustrated in the schematic diagram of FIG. 8. The first voltage drop element 340 and third voltage drop element 420 of FIG. 3 comprise first and second diodes 800, 810, respectively, as shown in FIG. 8. In addition, the second voltage drop element 350 of FIG. 3 comprises a resistor 820, as shown in FIG. 8. The first and second switches 390, 430 of FIG. 3 comprise first and second NMOS FETs 830, 840, as shown in FIG. 8. The voltage coupling element 410 of FIG. 3 comprises a PMOS capacitor 850 whose drain, source, and n-well are connected together and to the supply voltage V_{supply} provided by the power supply 315. The first inverter 370 of FIG. 3 comprises a Schmitt trigger 860, as shown in FIG. 8. The high threshold voltage Vₜₕ can be approximated by the following equation, in which V_{D} is the voltage drop across the first diode 800 and Vₜₙ is the turn-on threshold voltage of the Schmitt trigger 860:
Vₜₕ=2V_{D}+Vₜₙ (2)

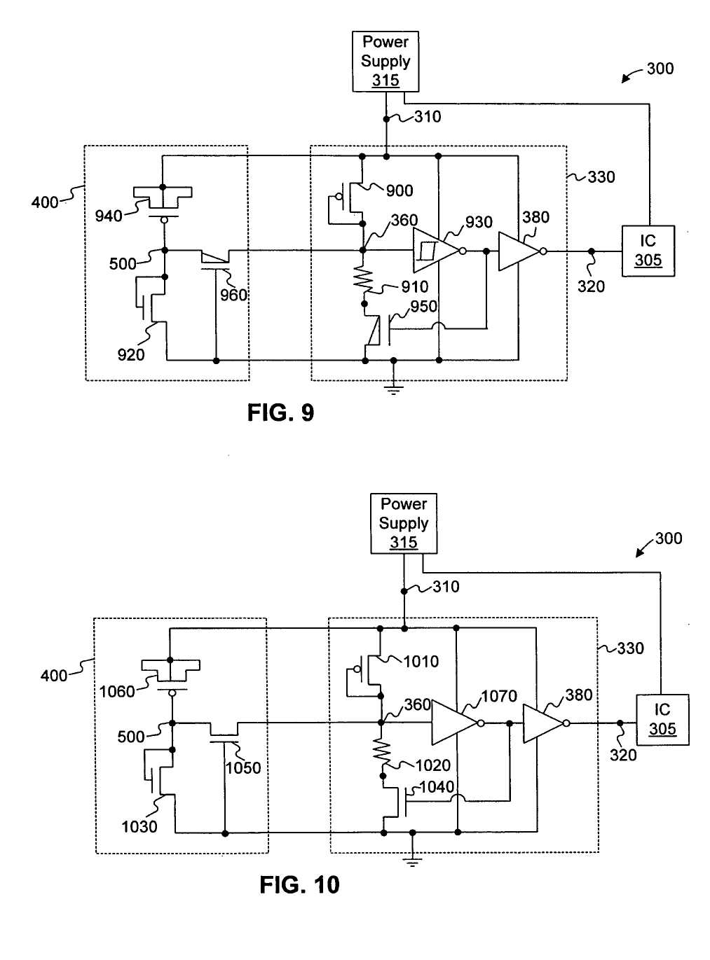

In yet another exemplary embodiment of the power-on reset circuit 300, illustrated in the schematic diagram of FIG. 9, the power-on reset circuit 300 is adapted to have enhanced sensitivity to a drop in the supply voltage V_{supply} 310 to respond quickly to a short-duration power disruption. In this example, the first voltage drop element 340 of FIG. 3 comprises a diode-connected PMOS FET 900, as shown in FIG. 9. The second voltage drop element 350 of FIG. 3 comprises a resistor 910, as shown in FIG. 9. The third voltage drop element 420 comprises a diode-connected NMOS FET 920, as shown in FIG. 9. The first inverter 370 of FIG. 3 comprises a Schmitt trigger 930, as shown in FIG. 9. The voltage coupling element 410 of FIG. 3 comprises a PMOS capacitor 940, as shown in FIG. 9, whose drain, source, and n-well are connected together to the supply voltage V_{supply} from the power supply 315. The first switch 390 and second switch 430 comprise “native” NMOS FETs 950, 960, respectively. Native NMOS FETs are directly fabricated in a lightly-doped P-type substrate, whereas typical NMOS FETs are fabricated in a heavily-doped P-well in a P-substrate twin-well CMOS process. Thus, native NMOS FETs have lower threshold voltages than typical NMOS FETs. For example, the threshold voltage of a native NMOS FET may be approximately 0.5 V lower than the threshold voltage of a typical NMOS FET fabricated using a 0.25 μm CMOS technology. The lower threshold voltages of the native NMOS FETs 950, 960 permit the native NMOS FETs 950, 960 to switch quickly. For example, the native NMOS FETs 950, 960 may be selected to have a threshold voltage of less than about 0.1 V. Thus, when the supply voltage V_{supply} 310 fluctuates rapidly, the native NMOS FETs 950 and 960, which serve as the first switch 390 and the second switch 430, respectively, can respond quickly by switching between the closed and open states to generate an effective and reliable reset signal 320.

Yet another exemplary embodiment of the power-on reset circuit 300 is illustrated in the schematic diagram of FIG. 10. The first voltage drop element 340 of FIG. 3 comprises a diode-connected PMOS FET 1010, as shown in FIG. 10. The second voltage drop element 350 of FIG. 3 comprises a resistor 1020, as shown in FIG. 10. The third voltage drop element 420 of FIG. 3 comprises a diode-connected NMOS FET 1030, as shown in FIG. 10. The first and second switches 390, 430 of FIG. 3 comprise first and second NMOS FETs 1040, 1050, respectively, as shown in FIG. 10. The voltage coupling element 410 of FIG. 3 comprises a PMOS capacitor 1060, as shown in FIG. 10, whose drain, source, and n-well are connected together to the supply voltage V_{supply} at node 310. However, instead of the Schmitt triggers 490, 570, 760, 860, 930 used in the embodiments of FIGS. 4, 5, 7, 8, and 9, respectively, the first inverter 370 of FIG. 3 comprises a standard inverter 1070, as shown in FIG. 10. This embodiment may be advantageous when the supply voltage V_{supply} contains a low level of noise because the narrower voltage window of the standard inverter 1070 permits the power-on reset circuit 300 greater sensitivity in detecting a power condition.

Although the present invention has been described in detail with regard to exemplary embodiments thereof, other variations are possible. For example, the first voltage drop element 340, the second voltage drop element 350, the third voltage drop element 420, the voltage coupling element 410, the first switch 390, and/or the second switch 430 of FIG. 3 may comprise other electronic components equivalent in function to the illustrative structures described herein. Also, the power-on reset circuit 300 may comprise a trigger unit 330 as shown in one exemplary embodiment, coupled to a rapid discharge unit 400 as shown in another exemplary embodiment. Furthermore, relative or positional terms, such as “first” and “second,” are used with respect to the exemplary embodiments and are interchangeable. Therefore, the appended claims should not be limited to the description of the versions contained herein.

What is claimed is:

1. A power-on reset circuit for an integrated circuit, the power-on reset circuit comprising:
a trigger unit including
a first voltage drop element including a first terminal and a second terminal, the first terminal for coupling to a supply voltage,
a second voltage drop element including a first terminal and a second terminal, the first terminal of the second voltage drop element being coupled to the second terminal of the first voltage drop element,
a first inverter including an input terminal and an output terminal, the input terminal of the first inverter being coupled to the first terminal of the second voltage drop element,
a second inverter including an input terminal and an output terminal, the input terminal of the second inverter being coupled to the output of the first inverter, and
a switch including a first terminal, a second terminal, and a third terminal, the first terminal of the switch coupled to the output terminal of the first inverter, the second terminal of the switch coupled to the second terminal of the second voltage drop element, and the third terminal of the switch for coupling to an electrical ground; and
a discharge unit to conduct a current from the trigger unit during a decrease of the supply voltage to decrease a voltage at the input of the first inverter, and substantially block current from the trigger unit during an increase of the supply voltage.

2. A power-on reset circuit according to claim 1, wherein the switch is a first switch, the discharge unit comprising:
a voltage coupling element including a first terminal and a second terminal, the first terminal for coupling to the supply voltage;
a third voltage drop element including a first terminal and a second terminal, the first terminal of the third voltage drop element coupled to the second terminal of the voltage coupling element, and the second terminal of the third voltage drop element for coupling to the electrical ground; and
a second switch including a first terminal and a second terminal, the first terminal of the switch coupled to the second terminal of the voltage coupling element, and the second terminal of the switch coupled to the input terminal of the first inverter.

3. A power-on reset circuit according to claim 2, wherein the third voltage drop element comprises a diode-connected NMOS FET.

4. A power-on reset circuit according to claim 2, wherein the voltage coupling element comprises a capacitor.

5. A power-on reset circuit according to claim 2, wherein the voltage coupling element comprises a PMOS capacitor.

6. A power-on reset circuit according to claim 2, wherein the first and third voltage drop elements comprise first and second diodes, respectively.

7. A power-on reset circuit according to claim 1, wherein at least one of the first and second switches comprises a native NMOS FET.

8. A power-on reset circuit according to claim 1, wherein the first inverter comprises a Schmitt trigger.

9. A power-on reset circuit according to claim 1, wherein the first inverter comprises a standard inverter.

10. A power-on reset circuit according to claim 1, wherein the first voltage drop element comprises a PMOS FET having a grounded gate.

11. A power-on reset circuit according to claim 1, wherein the first voltage drop element comprises a diode-connected PMOS FET.

12. A power-on reset circuit according to claim 1, wherein the second voltage drop element comprises a capacitor.

13. A power-on reset circuit according to claim 1, wherein the second voltage drop element comprises a resistor.

14. A power-on reset circuit for an integrated circuit, the power-on reset circuit comprising:
a trigger unit including
a first voltage drop element including a first terminal and a second terminal, the first terminal for coupling to a supply voltage,
a second voltage drop element including a first terminal and a second terminal, the first terminal of the second voltage drop element being coupled to the second terminal of the first voltage drop element, and
an inverter including an input terminal and an output terminal, the input terminal of the inverter being coupled to the first terminal of the second voltage drop element; and
a discharge unit including
a voltage coupling element including a first terminal and a second terminal, the first terminal for coupling to the supply voltage,
a third voltage drop element including a first terminal and a second terminal, the first terminal of the third voltage drop element being coupled to the second terminal of the voltage coupling element, and the second terminal of the third voltage drop element for coupling to an electrical ground, and
a switch including a first terminal and a second terminal, the first terminal of the switch being coupled to the second terminal of the voltage coupling element, and the second terminal of the switch being coupled to the input terminal of the inverter.

15. A power-on reset circuit according to claim 14, wherein the third voltage drop element comprises a diode-connected NMOS FET.

16. A power-on reset circuit according to claim 14, wherein the voltage coupling element comprises a capacitor.

17. A power-on reset circuit according to claim 14, wherein the voltage coupling element comprises a PMOS capacitor.

18. A power-on reset circuit according to claim 14, wherein the first and third voltage drop elements comprise first and second diodes, respectively.

19. A power-on reset circuit according to claim 14, wherein the switch comprises a native NMOS FET.

20. A power-on reset circuit according to claim 14, wherein the first inverter comprises a Schmitt trigger.
